(19) United States
(12) Patent Application Publication
(10) Pub. No.: US 2024/0022036 A1
(43) Pub. Date: Jan. 18, 2024

(54) METHOD AND APPARATUS FOR MANUFACTURING A TERMINAL APPARATUS FOR CONNECTING AT LEAST ONE ELECTRICAL OR ELECTRONIC COMPONENT FOR AN ELECTRICAL OR ELECTRONIC MODULE

(71) Applicant: ZF Friedrichshafen AG, Friedrichshafen (DE)

(72) Inventors: Ake Ewald, Bayreuth (DE); Fabian Hohmann, Hofbieber (DE); Stefan Hain, Speichersdorf (DE)

(73) Assignee: ZF Friedrichshafen AG, Friedrichshafen (DE)

(21) Appl. No.: 18/352,840

(22) Filed: Jul. 14, 2023

(30) Foreign Application Priority Data
Jul. 18, 2022 (DE) 102022207269.3

(51) Int. Cl. H01R 43/16

(52) U.S. Cl. CPC H01R 43/16; H02P 27/06

(57) ABSTRACT

A method for manufacturing a terminal apparatus for connecting at least one electrical or electronica component for an electrical or electronic module includes bending a pre-machined sheet metal element, having a first electric terminal device for connecting to a first electrical potential, a control terminal having at least one control contact, and a second electric terminal device arranged between the first electric terminal device and the control terminal for connecting to a second electrical potential, wherein the second electric terminal device has a path section including a first path for contact-connection with a terminal for the second electrical potential of the electrical or electronic component, and at least one second path arranged in parallel with the first path, and wherein a first bending section of the first path is bent into a lower plane than a second bending section of the second path in order to form the terminal apparatus.

### CROSS-REFERENCE TO RELATED APPLICATION

This application claims priority to German Application No. DE 10 2022 207 269.3, filed on Jul. 18, 2022, the entirety of which is hereby fully incorporated by reference herein.

### FIELD

The approach described herein relates to a method for manufacturing a terminal apparatus for connecting at least one electrical or electronic component for an electrical or electronic module, an apparatus for the actuation and/or execution of the method, a method for manufacturing an electrical or electronic module, a power converter, an electric axle drive for a motor vehicle, and a motor vehicle.

### BACKGROUND AND SUMMARY

Conventionally, in the field of power converters for electric axle drives of motor vehicles or, in other words, in the field of traction inverters for automobile applications, integrated B6 bridge modules, integrated half-bridge modules or discrete individual switches can be employed. In this connection, US2021313243A1 discloses a module having a leadframe, i.e. a connecting frame. The positioning of semiconductor components is thus substantially driven by the manufacturability of the leadframe which, in the original draft document, is represented in one instance as a sheet metal component. Outgoing currents, for example, can be divided between two terminals, thereby resulting in a potentially non-uniform distribution of currents and a consequent differential loading of semiconductors.

In this context, the approach described herein provides an improved method for manufacturing a terminal apparatus for connecting at least one electrical or electronic component for an electrical or electronic module, an improved apparatus for actuating and/or executing the method, an improved method for manufacturing an electrical or electronic module, an improved power converter, an improved electric axle drive for a motor vehicle and an improved motor vehicle, as claimed in the main claims. Advantageous configurations proceed from the sub-claims, and from the following description.

By means of a method proposed herein, a leadframe can be produced which permits a parallel arrangement of current-conducting paths, which are or can be partly connected to semiconductor source potentials and partly not. The parallel arrangement of the current-conducting paths permits parallel current conduction, without the connection of the semiconductor which can be a power semiconductor.

Advantages achievable by means of the approach envisaged are particularly provided in that an in-module semiconductor contact-connection of a power module of a power converter for an electric axle drive of a motor vehicle can be achieved in an advantageous manner. By way of distinction from a module based upon a conventional leadframe design, according to embodiments of the power module, it can be achieved, for example, that current conduction between semiconductor components, more specifically between power semiconductor components in the region of the “power source” or, in other words, a connection or power connection of semiconductor components, is executed in a consistent manner. Thus, in particular, a uniform distribution of electric currents can be achieved, as a result of which a consistent loading of semiconductors is obtainable. According to embodiments, for example, a power module can be executed which comprises a centralized source tap or, in other words, a power terminal which is centrally or medially arranged with respect to a plurality of power semiconductor components. Thus, in particular, by means of the central power-source connection, a uniform current distribution between power semiconductor components is permitted. Moreover, particularly in the power module, a connection of all control terminals of power semiconductor components to a corresponding terminal pin of the power module can be provided.

A method for manufacturing a terminal apparatus for connecting at least one electrical or electronic component for an electrical or electronic module comprises a bending step. In the bending step, a pre-machined sheet metal element is bent, having a first electric terminal device for connecting to a first electrical potential, a control terminal having at least one control contact, and a second electric terminal device which is arranged between the first electric terminal device and the control terminal, for connecting to a second electrical potential, wherein the second electric terminal device has a path section which comprises a first path for contact-connection with a terminal for the second electrical potential of the electrical or electronic component, and at least one second path which is arranged in parallel with the first path. In the bending step, a first bending section of the first path is bent into a lower plane than a second bending section of the second path in order to form the terminal apparatus.

This method can be implemented, for example, in a hardware or in a software, or in a hybrid arrangement of software and hardware, for example in a control device.

The terminal apparatus can be a leadframe, i.e., for example, a metallic terminal frame. The sheet metal element can be formed of a flat sheet metal. Pre-machined sheet metal can be understood as a die-stamped, pre-cut and/or laser-cut sheet metal element. The pre-machined sheet metal can be configured in a one-piece design, such that the first electric terminal device, the control terminal and/or the second electric terminal device of the terminal apparatus can be integrally formed. Prior to the bending step, the first electric terminal device, the control terminal and/or the second electric terminal device can be arranged in a common plane. The electrical or electronic component can be a semiconductor component, for example a power semiconductor such as an insulated-gate bipolar transistor, or “IGBT” for short, and/or a diode and/or a single-pole component, such as a MOSFET. The electronic module can be a power module, for example of a power converter for an electric axle drive of a motor vehicle. The first terminal device is employed to connect the module/power module to the first electrical potential, which can be, for example, an electrical drain potential. The control contact can be a gate pin. The control terminal can also comprise a second control contact, for example in the form of a Kelvin-source pin. The first path can be an electrically conductive or current-conducting path for contact-connection with the terminal for the second electrical potential of the electrical or electronic component. The second path can likewise be an electrically conductive or current-conducting path. The second path can for example be configured to correspond to the first path prior to the bending step and/or be a second path which is arranged in parallel with the first path. The second electrical potential can be a source potential, such that the terminal for the second electrical potential can be a source potential terminal. A “lower plane” is to be understood as a plane which is bent lower in the bending direction. Since, in the bending step, the first bending section of the first path is bent into a lower plane than the second bending section of the second path, the first path can advantageously be employed, further to the bending step, for contact-connection with the terminal for the second electrical potential of the electrical or electronic component, whereas the second path, further to the bending step, is not contact-connected with the terminal for the second electrical potential, but is arranged with a clearance to the terminal for the second electrical potential.

In the bending step, a first section length of the first bending section and/or a second section length of the second bending section can essentially correspond to a first component length of the electrical or electronic component. The first bending section can thus lie on the section length over the largest possible bearing area. The component length may be a length running perpendicular to the bending direction

According to one embodiment, in the bending step, the first bending section and/or the second bending section can be bent into a wave shape. In this case, the first bending section, for example along a length of the first bending section, can be bent into at least two wave-shaped bends and/or the second bending section, along a length of the second bending section, can be bent into at least four wave-shaped bends. More bends may be used to keep the depth of the bend running perpendicular to the length low overall, such that the first bending section with fewer bends is bent deeper overall in order to be able to make contact with the terminal for the second electrical potential, and the second bending section with more bends is bent not as deep overall in order not to make contact with the terminal for the second electrical potential.

The method can further comprise a die-stamping or laser cutting step, which precedes the bending step, in which a sheet metal blank is die-stamped or laser cut in order to obtain the pre-machined sheet metal element, in particular wherein, in the die-stamping and/or laser cutting step, the sheet metal blank is die-stamped or laser cut such that a gap between the first electric terminal device and the path section is generated. The sheet metal blank can be a flat sheet metal blank. By means of the gap, it can be ensured that no direct connection exists between the first electric terminal device and the second electric terminal device.

The method can moreover comprise a further bending step, in which the control contact is bent in a direction opposite to the path section. In the further bending step, the second control contact can also be bent in a corresponding manner to the control contact. The control contact and/or the second control contact can be centrally bent, for example, through for example 90 degrees. If the bending of the bending sections of the path section in the bending step can be understood as downwards bending, then the control contacts can be bent upwards, opposite thereto. The control contacts can be bent extending transversely/perpendicularly to a main extension plane of the first electric terminal device.

In the bending step, a further first path of the path section, which is arranged in parallel with the first path, for contact-connection with a further terminal for the first potential of the electrical or electronic component, can furthermore be bent in a corresponding manner to the first bending section. The further first path can also be an electrically conducting or current-conducting path. The first electrical potential can be a drain potential, such that the further terminal for the first electrical potential can be a drain terminal. Thus, the path section can comprise the first path for contact-connection with the second potential, the further first path for contact-connection with the first potential, and the second path, which is arranged with a clearance from both potentials. Thus, in the leadframe, a parallel arrangement of current-conducting paths is permitted, which are partly connected to the semiconductor source potentials, and partly not. The parallel arrangement of the current-conducting paths permits parallel current conduction, without the connection of the power semiconductor. For the connection of the terminal/chip, the leadframe, on the upper side of the terminal/chip and/or of the further terminal, is bent downwards. In the region of the parallel paths, an alternative form of bending is employed for the second bending section, which can correspond to the identical length from the bend leadframe to the chip. This alternative form which is executed, for example, as a wave shape, is selected such that the clearance to the electrical or electrical component, or to a circuit board such as a direct bonded copper substrate, or “DBC” for short, on which the component is arranged, permits the isolation of the leadframe from the component or from the direct bonded copper substrate.

In the bending step, the sheet metal can be bent such that it further comprises at least one second path section which is arranged between the first electric terminal device and the control terminal, which comprises a third path for contact-connection with a terminal for the second electrical potential of a second electrical or electronic component, and at least one fourth path which is arranged in parallel with the third path wherein, in the bending step, a third bending section of the third path is bent into a lower plane than a fourth bending section of the fourth path, or the third bending section and the fourth bending section are bent in a corresponding manner to the first bending section. The third path and/or fourth path can be configured in an electrically conductive or current-conducting manner. Thus, by means of the second path section, a second electrical or electronic component, which can also be a semiconductor component, can further be connected to the terminal apparatus. The third bending section can thus be shaped according to the first bending section, wherein the fourth bending section, as per the second bending section, is either not contact-connected with the second component, and is thus bent to a shorter depth, in accordance with the second bending section, or the fourth bending section, as per the further first bending section, can be shaped for contact-connection with a terminal for the first electrical potential of the second component.

According to one embodiment, in the bending step, the third bending section and the fourth bending section of the second path section can be bent, wherein the path section and the second path section are arranged adjacently to one another or one behind the other. Electrical or electronic components which are arranged adjacently, or one behind another, can be contact-connected accordingly.

A method for manufacturing an electrical or electronic module comprises a resourcing step and a contact-connection step. In the resourcing step, a terminal apparatus, which has been produced by the employment of the above-mentioned method in one of the above-mentioned variants, and the electrical or electronic component are provided. In the contact-connection step, the first bending section is contact-connected with the terminal for the second electrical potential of the electrical or electronic component, in order to produce the electrical or electronic module. In the contact-connection step, the second bending section can furthermore be arranged with a clearance to the terminal for the second electrical potential and/or with a clearance to the further terminal for the first potential of the electrical or electronic component, in order to produce the electrical or electronic module.

The method can also comprise a fastening step, wherein the first bending section is soldered or sintered to the terminal for the second electrical potential of the electrical or electronic component and/or the further first bending section is soldered or sintered to a terminal for the first electrical potential of the electrical or electronic components, and/or at least one connecting section of the terminal apparatus can be soldered or sintered to a substrate which carries the electrical or electronic component, for example a direct bonded copper substrate, or to another circuit board. A stable fastening of the terminal apparatus to the terminals and/or to the substrate can thus be achieved.

The method can further comprise a molding step, wherein at least the path section and the electrical or electronic component which are contact-connected by the first bending section are over-molded. An additional protection and additional stabilization of the first bending section and/or of the electrical or electronic component can thus be achieved.

According to one embodiment, the method can further comprise a step for removing an edge region of the sheet metal blank or the pre-machined sheet metal element. In the removal step, for example, the edge region can be cut off, removed by laser cutting and/or stamped off. The edge region can be an edge section of the pre-machined sheet metal element which surrounds the first electric terminal device, the control terminal and the second electric terminal device.

The method can also comprise a bonding step, wherein a gate terminal or the electrical or electronic component is directly or indirectly connected to the control contact and/or a signal terminal of the electrical or electronic component is directly or indirectly connected to the second control contact and/or a further signal terminal, which can be a Kelvin-source terminal, of the electrical or electronic component is directly or indirectly connected to the first electric terminal device, for example to the path section. In the bonding step, connections can be formed e.g. by means of bonding wires. An operational electrical or electronic module can thus be provided.

An electrical or electronic module comprises a substrate, which can be a direct bonded copper substrate or another circuit board, and at least one electrical or electronic component which is arranged on the substrate, and a terminal apparatus produced by a method according to one of the above-mentioned variants, wherein the first bending section of the first path is contact-connected with the terminal for the second electrical potential of the electrical or electronic component and/or the second bending section of the second path is arranged with a clearance to the terminal for the second electrical potential and/or to a further terminal for the first electrical potential of the electrical or electronic component.

The approach envisaged herein further provides an apparatus which is configured to execute, actuate or implement the steps of a variant of the method presented herein in corresponding devices. By means of these variants of embodiment of the approach envisaged, in the form of an apparatus, the fundamental object of this approach can also be fulfilled in a rapid and efficient manner.

An apparatus can be an electrical device which processes electrical signals, for example sensor signals, and delivers an output of control signals in accordance therewith. The apparatus can comprise one or more interface(s), the configuration of which can be hardware-based and/or software-based. In a hardware-based embodiment, the interfaces can be, for example, an element of an integrated circuit in which functions of the apparatus are implemented. Interfaces can also be dedicated and integrated switching circuits, or can be at least partially comprised of discrete components. In a software-based embodiment, interfaces can be software modules which, for example, are present in a microcontroller, in addition to other software modules.

A computer program product is also advantageous, having program code which can be saved on a machine-readable medium, such as a semiconductor memory, a hard disk memory or an optical memory, and is employed for executing the method in one of the above-mentioned embodiments when the program is run on a computer or an apparatus.

The invention additionally relates to a power converter, particularly an inverter, for a motor vehicle, having a terminal apparatus produced by the employment of a method according to one of the above-mentioned variants. The power converter is characterized in that the terminal apparatus is configured in the manner described.

The power converter can be configured in the form of a power inverter or inverter. By the employment of a power converter, the requisite alternating current for the operation of the electrical machine can be delivered.

The invention further relates to an electric axle drive for a motor vehicle having at least one electrical machine, a transmission device, and an above-mentioned power converter, particularly an inverter. The electric axle drive is characterized in that the power converter is configured in the manner described above.

By the employment of the transmission device, a torque which is generated by the electrical machine is converted into a drive torque for driving at least one wheel of the motor vehicle. The transmission device can comprise a gearbox for stepping down the rotational speed of the electrical machine, and can optionally comprise a differential.

The invention additionally relates to a motor vehicle having an electric axle drive and/or a power converter. The motor vehicle is characterized in that the electric axle drive and/or the power converter are configured as per one of the above-mentioned variants.

Exemplary embodiments of the approach envisaged herein are represented in the drawings and described in further detail in the following description.

### BRIEF DESCRIPTION OF THE DRAWINGS

FIG. 1 shows a schematic representation of an exemplary embodiment of a motor vehicle;

FIG. 2 shows a schematic representation of an exemplary embodiment of a power converter for an electric axle drive of a motor vehicle;

FIG. 3 shows a schematic representation of an exemplary embodiment of a terminal apparatus for connecting at least one electrical or electronic component for an electrical or electronic module;

FIG. 4 shows a perspective representation of a first bending section and a second bending section of a terminal apparatus according to one exemplary embodiment;

FIG. 5 shows a schematic view of an electrical or electronic module according to one exemplary embodiment;

FIG. 6 shows a lateral cross-sectional representation of a first bending section and a second bending section of an electrical or electronic module according to one exemplary embodiment;

FIG. 7 shows a schematic view of an electrical or electronic module according to one exemplary embodiment;

FIG. 8 shows a perspective view of different production stages during an exemplary production process of a terminal apparatus according to one exemplary embodiment, and an electrical or electronic module according to one exemplary embodiment;

FIG. 9 shows a perspective view of different production stages during an exemplary production process of a terminal apparatus according to one exemplary embodiment;

FIG. 10 shows a flow diagram of an exemplary embodiment of a method for manufacturing a terminal apparatus for connecting at least one electrical or electronic component for an electrical or electronic module; and

FIG. 11 shows a flow diagram of an exemplary embodiment of a method for manufacturing an electrical or electronic module.

### DETAILED DESCRIPTION

In the following description of preferred exemplary embodiments of the approach presented herein, identical or similar reference numbers are employed for elements having a similar action which are represented in the various figures, wherein any repeated description of these elements is omitted.

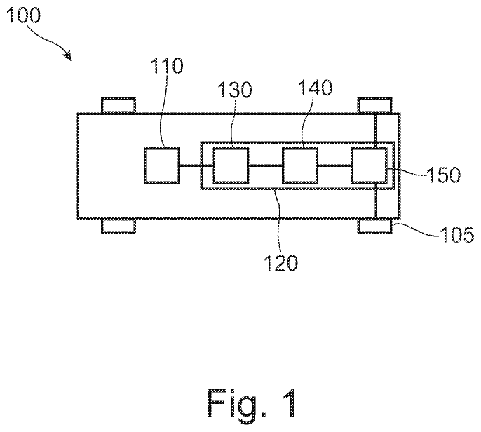

FIG. 1 shows a schematic representation of an exemplary embodiment of a motor vehicle 100. Of the motor vehicle 100 represented in FIG. 1, wheels 105, wherein four wheels 105 are represented by way of an example only, an electrical energy store 110, for example a battery, and an electric axle drive 120 are shown. The electric axle drive 120 comprises a power converter 130, an electrical machine 140 and a transmission device 150.

Electrical energy for operating the electrical machine 105 is delivered by an energy supply device, in this case the electrical energy 110. The electrical energy store 110 is configured to supply a direct current which, by the employment of a power converter 130 of the electric axle drive 120, is converted into an alternating current, for example a three-phase alternating current, and is delivered to the electrical machine 140. A shaft which is driven by the electrical machine 140 is coupled to at least one wheel 105 of the motor vehicle 100, either directly or via a transmission device 150. The motor vehicle 100 can thus be propelled by the employment of the electrical machine 140. According to one exemplary embodiment, the electric axle drive 120 comprises a housing in which the power converter 130, the electrical machine 140 and the transmission device 150 are arranged.

In particular, the power converter 130 and the components thereof are addressed in greater detail, with reference to the following figures.

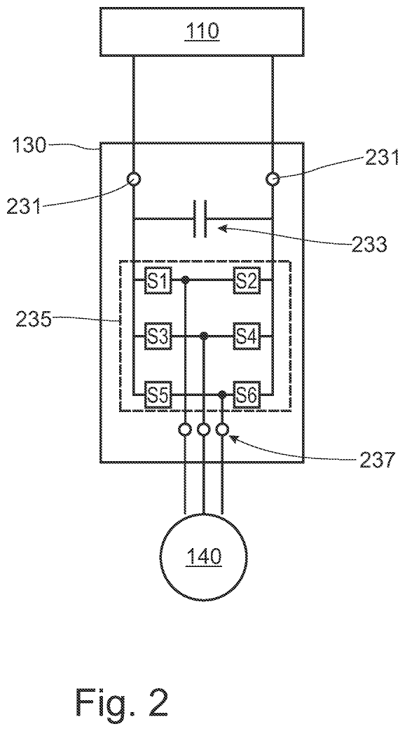

FIG. 2 shows a schematic representation of an exemplary embodiment of a power converter 130 for an electric axle drive of a motor vehicle. The power converter 130 corresponds or is similar to the power converter according to FIG. 1. For illustrative purposes, moreover, additionally to the power converter 130, the electrical energy store 110 and the electrical machine 140 of the electric axle drive are also represented in FIG. 2. The power converter 130 comprises DC terminals 231, a link capacitor 233, a plurality of power modules 235 and AC terminals 237.

The DC terminals 231 are provided for the delivery of a direct current from the electrical energy store 110 of the motor vehicle. In other words, the power converter 130 is connectable or connected, via the DC terminals 231, to the electrical energy store 110. The link capacitor 233 is electrically connected to the first of the DC terminals 231 and to the second of the DC terminals 231. The alternating current terminals 237 are provided for the delivery of an alternating electric current for the electrical machine 140 of the electric axle drive. In other words, the power converter 130 is connectable or connected, via the AC terminals 237, to the electrical machine 140. The DC terminals 231 and/or the AC terminals 237, for example, are formed to respectively accommodate one end of a power cable, and are mechanically and electrically contact-connected, for example by screwing, clamping or soldering.

The power modules 235 comprise switching devices, and are designed to convert direct current into alternating current. The power modules 235, which are also described hereinafter as electrical or electronic modules, will now be addressed in greater with reference to the following figures. According to the exemplary embodiment represented here, the power converter 130, for exemplary purposes only, comprises six power modules 235, in this case a first power module S1, a second power module S2, a third power module S3, a fourth power module S4, a fifth power module S5 and a sixth power module S6. The power modules 235 or S1, S2, S3, S4, S5 and S6 are interconnected in a B6 bridge circuit. A first of the DC terminals 231 is electrically connected to a first terminal of the first power module S1, to a first terminal of the third power module S3, and to a first terminal of the sixth power module S5. A second of the DC terminals 231 is electrically connected to a first terminal of the second power module S2, to a first terminal of the fourth power module S4, and to a first terminal of the sixth power module S6. A first of the AC terminals 237 is electrically connected to a second terminal of the first power module S1 and to a second terminal of the second power module S2. A second of the AC terminals 237 is electrically connected to a second terminal of the third power module S3 and to a second terminal of the fourth power module S4. A third of the AC terminals 237 is electrically connected to a second terminal of the fifth power module S5 and to a second terminal of the sixth power module S6.

According to one exemplary embodiment, the power converter 130 can be operated in a reverse direction, such that the electrical machine 140 can be employed as a generator for charging the electrical energy store 110.

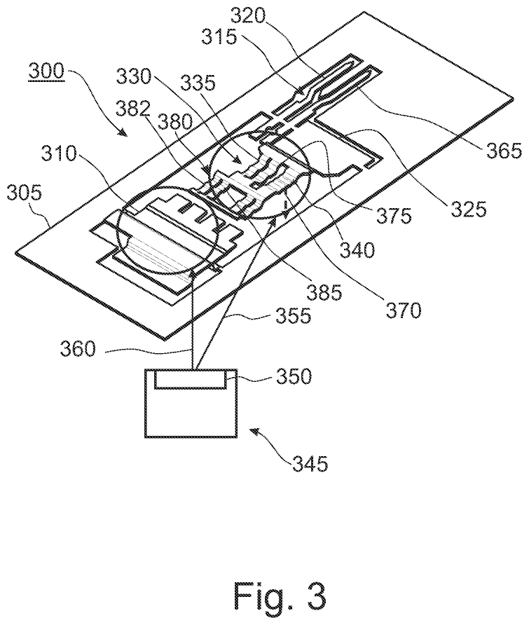

FIG. 3 shows a schematic representation of an exemplary embodiment of a terminal apparatus 300 for connecting at least one electrical or electronic component for an electrical or electronic module. According to one exemplary embodiment, the electrical or electronic module is the power module described in FIG. 2, which is suitable for use with the power converter described in FIG. 1 or 2 for the electric axle drive described in FIG. 1 or 2 of the motor vehicle described in FIG. 1 or 2.

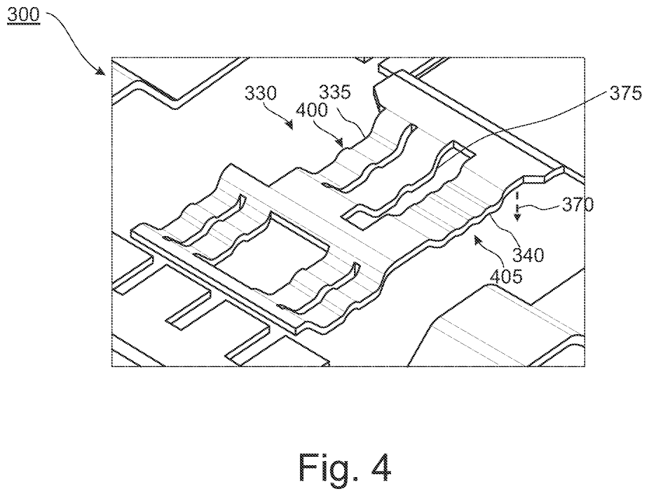

The terminal apparatus 300 comprises a pre-machined sheet metal element 305 having a first electric terminal device 310 for connecting to a first electrical potential, a control terminal 315 having at least one control contact 320, and a second electric terminal device 325 which is arranged between the first electric terminal device 310 and the control terminal 315, for connecting to a second electrical potential, wherein the second electric terminal device 325 has a path section 330 which comprises a first path 335 for contact-connection with a terminal for the second electrical potential of the electrical or electronic component, and at least one second path 340 which is arranged in parallel with the first path 335. A first bending section of the first path 330 is bent into a lower plane than a second bending section of the second path 340. The first bending section and the second bending section are shown in more detail in FIG. 4.

FIG. 3 further shows an apparatus 345 which designed to execute and/or actuate the manufacture of the terminal apparatus 300. To this end, the apparatus 345 comprises an output device 350, which is configured to generate an output of a bending signal 355 in order to execute a bending of the first bending section of the first path 330 into a lower plane than the plane of the second bending section of the second path 340. FIG. 3 represents an outcome for the achievement of the bent states of the paths 335, 340 executed by the bending signal 355.

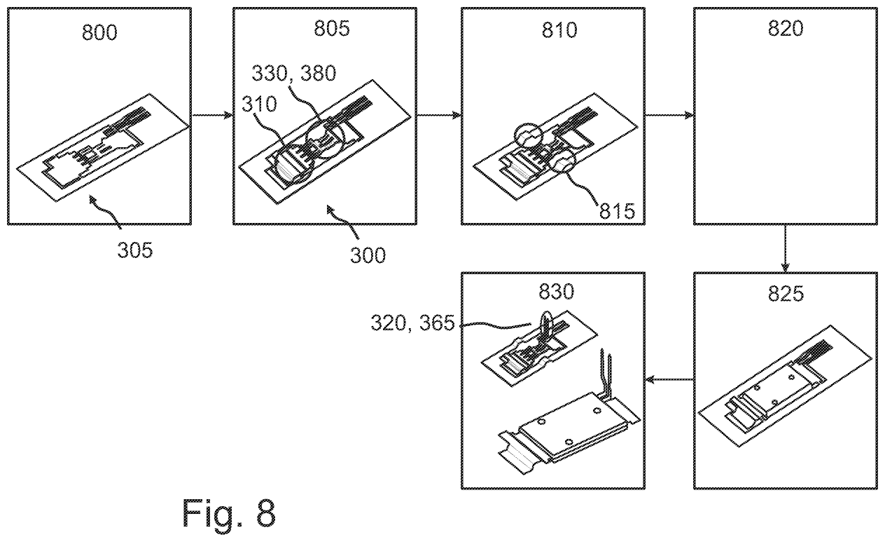

According to this exemplary embodiment, the terminal apparatus 300 is configured in the form of a “leadframe”, i.e. as a metallic connecting frame. The pre-machined sheet metal element 305, according to the present exemplary embodiment, is a flat sheet metal element. The pre-machined sheet metal element 205 according to the present exemplary embodiment has been die-stamped, cut-out and/or laser-cut to form the first electric terminal device 310, the control terminal 315 and the second electric terminal device 325. According to the present exemplary embodiment, the pre-machined sheet metal element 205 is configured in a one-piece design, such that the first electric terminal device 310, the control terminal 315 and/or the second electric terminal device 325 of the terminal apparatus 300 are formed in a mutually integral manner. Prior to the output of the bending signal 355, which generates the bent state of the paths 335, 240 represented here, the first electric terminal device 310, the control terminal 315 and/or the second electric terminal device 325, according to one exemplary embodiment, were arranged in a common plane—c.f. FIG. 8. In an optional manner only, the apparatus 345 according to the present exemplary embodiment is furthermore configured to generate the output of a further bending signal 360 which also executes a bending of the first electric terminal device 310.

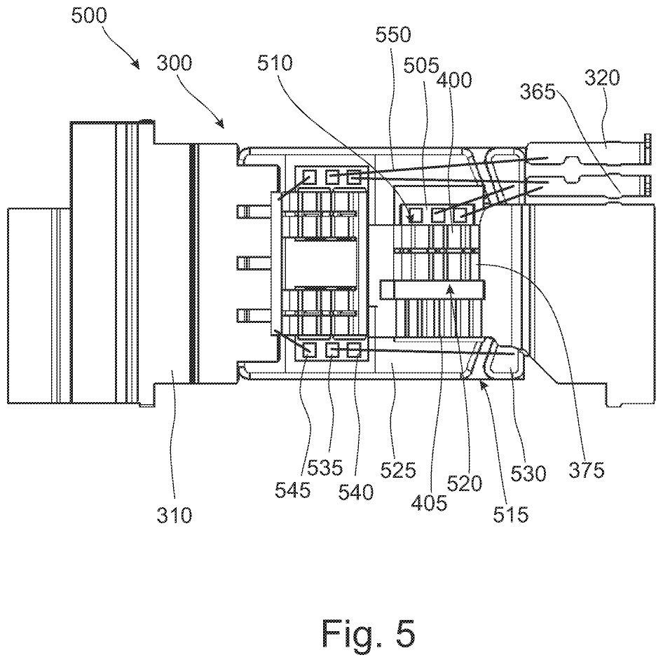

According to the present exemplary embodiment, the first terminal device 310 is employed for connecting the module/power module to the first electrical potential, which is configured, for example, as an electrical drain potential. According to the present exemplary embodiment, the control contact 320 is configured as a gate pin. According to the present exemplary embodiment, the control terminal 315 also comprises a second control contact 365, which is configured here, for exemplary purposes, as a Kelvin-source pin. According to the present exemplary embodiment, the first path 335 is configured as an electrically conductive or current-conducting path, and is employed for contact-connection with the terminal for the second electrical potential of the electrical or electronic component—see FIG. 5. According to the present exemplary embodiment, the second path 340 is also configured as an electrically conducting or current-conducting path, wherein the second path 340 is not configured for the contact-connection of a terminal for an electrical potential of the electrical or electronic component. The second path 340 was, for example, prior to the bending executed by the bending signal 355, configured to correspond to the first path 335, c.f. FIG. 8, and/or, according to the present exemplary embodiment, is a second path 340 which is arranged in parallel with the first path 335. According to the present exemplary embodiment, the second electrical potential is configured as a source potential, such that the terminal for the second electrical potential, according to the present exemplary embodiment, is a source potential terminal. The term “lower plane” is to be understood as a plane which is bent lower in the bending direction 370. Given that, by means of the bending signal 355, the first bending section of the first path 335 is bent into a lower plane than the second bending section of the second path 340, the first path 335 can advantageously be employed after the bending process for contact connection with the terminal for the second electrical potential of the electrical or electronic component, whereas the second path 340 does not contact-connect the terminal for the second electrical potential after the bending, but is arranged with a clearance to the terminal for the second electrical potential.

The path section 330 of the terminal apparatus 300, according to the present exemplary embodiment, additionally comprises a further first path 375, which is arranged in parallel with the first path 335, wherein the further first path 375 is bent for contact-connection with a further terminal for the first potential of the electrical or electronic component, in a corresponding manner to the first bending section. According to the present exemplary embodiment, the further first path 375 is also an electrically conductive or current-conducting path. According to one exemplary embodiment, the further first path 375 has also been bent by the bending signal 255. The first electrical potential can be a drain potential, such that the further terminal for the first electrical potential can be a drain terminal.

According to the present exemplary embodiment, the pre-machined sheet metal element 305 further comprises at least one second path section 380, which is arranged between the first electric terminal device 310 and the control terminal 315, and which comprises a third path 382 for contact-connection with a terminal for the second electrical potential of a second electrical or electronic component, and at least one fourth path 385 which is arranged in parallel with the third path 382 wherein, according to the present exemplary embodiment, a third bending section of the third path 382 and a fourth bending section of the fourth path 385 are bent in a corresponding manner to the first bending section or, according to an alternative exemplary embodiment, the third bending section of the third path 382 is bent into a lower plane than the fourth bending section of the fourth path 385. According to this exemplary embodiment, the third path 382 and/or the fourth path 385 are also configured as electrically conductive or current-conducting. According to one exemplary embodiment, the third path 382 and/or the fourth path 385 are also bent in response to the bending signal 255.

According to this exemplary embodiment, the path section 330 and the second path section 380 are arranged with an offset, one behind the other. According to an alternative exemplary embodiment, the path section 330 and the second path section 380 are arranged adjacently to one another, or are configured in a flush arrangement, one behind the other. According to this exemplary embodiment, the path section 330 is arranged to face the control terminal 315, whereas the second path section 380 is arranged to face the first electric terminal device 310.

According to the present exemplary embodiment, the pre-machined sheet metal element 305 further comprises at least one third path section, which is arranged between the first electric terminal device 310 and the control terminal 315, and which comprises a fifth path for contact-connection with a terminal for the second electrical potential of an electrical or electronic component, and at least one sixth path which is arranged in parallel with the fifth path wherein, according to this exemplary embodiment, a fifth bending section of the fifth path and a sixth bending section of the sixth path are bent in a manner which corresponds to the first bending section or, according to an alternative exemplary embodiment, the fifth bending section of the fifth path is bent into a lower plane than the sixth bending section of the sixth path. According to this exemplary embodiment, the fifth path and/or the sixth path are also configured as electrically conductive or current-conducting. According to one exemplary embodiment, the fifth path and/or the sixth path have also been bent by the bending signal 255. According to this exemplary embodiment, the second path section 380 and the third path section are arranged adjacently to one another, such that the third path 382, the fourth path 385, the fifth path and the sixth path are oriented in parallel.

FIG. 4 shows a perspective representation of a first bending section 400 and a second bending section 405 of a terminal apparatus 300 according to one exemplary embodiment. This can be the terminal apparatus 300 described in FIG. 3.

According to this exemplary embodiment, the first bending section 400 and/or the second bending section 405 are bent into a wave shape. The first bending section 400, for example along a length of the first bending section 400, is bent into at least two wave-shaped bends and/or the second bending section 405, along a length of the second bending section 405, is bent into at least four wave-shaped bends.

FIG. 4 shows a detailed view of the parallel-arranged current-conducting paths 335, 340, 375.

The parallel arrangement of current-conducting paths 335, 340, 375 permits a parallel routing of current, without the connection of a power semiconductor. For the connection of a terminal/chip, it is necessary for the leadframe to be bent down onto the upper side of the chip. In the region of the parallel paths 335, 375, for the second path 340, an alternative form of bending is executed wherein, according to this exemplary embodiment, the identical length of the bent leadframe corresponds to the chip. This alternative form, which is executed here in a wave shape, by way of an example, is selected such that the clearance to a circuit board, for example to a DBC board, permits an isolation of the leadframe vis-à-vis the DBC board.

FIG. 5 shows a schematic view of an electrical or electronic module 500, according to one exemplary embodiment. The electrical or electronic module 500 comprises a terminal apparatus 300 and an electrical or electronic component 505. These can be the terminal apparatus 300 described in FIG. 3 or 4 and the electrical or electronic component 505 described in FIG. 3 or 4.

According to this exemplary embodiment, the electrical or electronic module 500 is configured as a power module for an electric axle drive of a motor vehicle.

The first bending section 400 is contact-connected with the terminal 510 for the second electrical potential of the electrical or electronic component 505. In FIG. 5, the terminal 510 is covered by the first path. According to this exemplary embodiment, the second bending section 405 is arranged with a clearance to the terminal 510 for the second electrical potential and/or with a clearance to a further terminal 520 for the first potential of the electrical or electronic component 505.

According to this exemplary embodiment, the electrical or electronic module 500 further comprises a substrate 515, on which the electrical or electronic component 505 is arranged. According to this exemplary embodiment, the substrate 515 comprises a first electrical contact section 525 and a second electrical contact section 530, wherein the contact sections 525, 530 are electrically isolated from one another. According to this exemplary embodiment, the module 500 further comprises a plurality of electrical or electronic components 505 which are arranged on the substrate 515 and which, according to this exemplary embodiment, are respectively configured as semiconductor components, each having a terminal 510 for the second electrical potential, a further terminal 520 for the first electrical potential, a gate terminal 535, a signal terminal 540 and/or a further signal terminal 545, wherein the terminals 510 for the second electrical potential of all components 505 are electrically connected to the first contact section 525. The first electric terminal device 310, according to this exemplary embodiment, is electrically connected to the first contact section 525, and the second electric terminal device 325, according to this exemplary embodiment, is electrically connected to further terminals 520 for the first electrical potential of all the components 505. Each of the path sections is respectively arranged above one of the components 505. The first control contact 320 is electrically connected to the gate terminals 535 of all the components 505, and the second control contact 365 is electrically connected to the signal terminals 540 of all the components 505. According to this exemplary embodiment, the further signal terminals 545 which, according to this exemplary embodiment, are Kelvin-source terminals, are directly or indirectly connected to the first electric terminal device 310. The connections are formed, for example, by means of bonding wires 550. According to an alternative exemplary embodiment, the electrical or electronic component 505 is configured as an insulated-gate bipolar transistor, or “IGBT” for short, and/or as a diode, and/or as a single-pole component, such as a MOSFET.

A first section length of the first bending section 400 and/or a second section length of the second bending section 405, according to the present exemplary embodiment, essentially correspond to a first component length of the electrical or electronic component 505.

The first bending section 400, according to this exemplary embodiment, is soldered or sintered to the terminal 510 for the second electrical potential of the electrical or electronic component 505 and/or the further first bending section of the further first path 375 is soldered or sintered to the further terminal 520 for the first electrical potential of the electrical or electronic component 505 and/or, according to one exemplary embodiment, at least one connecting section of the terminal apparatus is soldered or sintered to the substrate 515, which is configured here, for exemplary purposes, as a direct bonded copper substrate or, alternatively, as another circuit board.

The terminal apparatus 300 envisaged here advantageously permits an internal contact-connection of a power semiconductor assembly.

The terminal apparatus 300 envisaged here is employable in conjunction with all inverter systems, including entry-, mid- and high-platform systems, Formula E, 8-speed automatic transmissions, and charging devices for vehicle batteries—“on-board chargers”—or DC/DC converters.

A module based upon a leadframe design poses a challenge, in that all the terminals are formed from flat sheet metal. Forming operations in the third dimension, in order to provide e.g. insulating clearances or different connection heights for components will, by definition, result in greater clearances vis-à-vis the flat sheet metal. A restrictive design of this type results in minimum clearances between structures and semiconductors, which cannot be selected in consideration of thermal and electrical factors only, such that a module must be constructed to larger dimensions than necessary, or corresponding design compromises must be addressed, including specific semiconductor arrangements or power restrictions.

An electrical or electronic module 500, which can also be described as a “power module”, is therefore envisaged which:
in the leadframe (“connecting frame”), permits a parallel arrangement of current-conducting paths, which are partly connected to semiconductor source potentials and partly not,
permits an asymmetrical chip distribution in the package,
permits a connection of all the gate terminals 535 to the control contact 320 which, according to the present exemplary embodiment, is a gate pin,
has a common connecting substrate 515, in this case a DBC (direct bonded copper) structure, which maintains an optimum mutual thermal clearance between all the semiconductors,
permits optimum heat evacuation by means of the DBC board, and
according to one exemplary embodiment, comprises a “mold compound” which protects semiconductors from external influences, provides electrical insulation and transmits the requisite forces for a sintering process—see FIG. 8.

The optimum positioning of electrical or electronic components 505, for example in the form of semiconductors, on a circuit board, for example a “DBC” board, is based upon minimal thermal resistance. The connection of semiconductors, according to one exemplary embodiment, is achieved by means of a sintered or soldered connection. According to one exemplary embodiment, the combination of the leadframe and chips has been formed by means of a sintered or soldered connection.

According to one exemplary embodiment, connection of the power-drain terminal to the DBC board has been executed by means of a welded, sintered and/or soldered connection. The same applies, in an analogous manner, to the emitter terminal of an IGBT or the anode of a diode. Connection to the gate and Kelvin-source (Kelvin-emitter) pins 320, 365 is executed by means of bonding wires 550.

Gate terminals 535 are routed via islands in the right-hand region of the DBC board, whereas Kelvin-source terminals 540 for the upper semiconductors are led directly to the Kelvin-source pin 365. The lower, in this case third semiconductor, according to one exemplary embodiment, is contact-connected from the upper left-hand semiconductor via the power-source clip by means of additional bonding wires. Alternatively, according to one exemplary embodiment, the power-source clip is employed wherein, as a result of the load path in the clip, greater corruptions of potential can occur than in the variant having additional bonding wires to the Kelvin-source islands on the semiconductor.

The substrate 515/DBC, according to this exemplary embodiment, is formed of an insulating ceramic having the highest possible thermal conductivity, e.g. silicon nitride, or “SiN” for short, aluminum oxide, or “Al₂O₃” for short, or aluminum nitride, or “AlN” for short, coated on the upper side and/or underside with copper. The underside, according to one exemplary embodiment, is coated e.g. with silver, for a sintered or soldered connection.

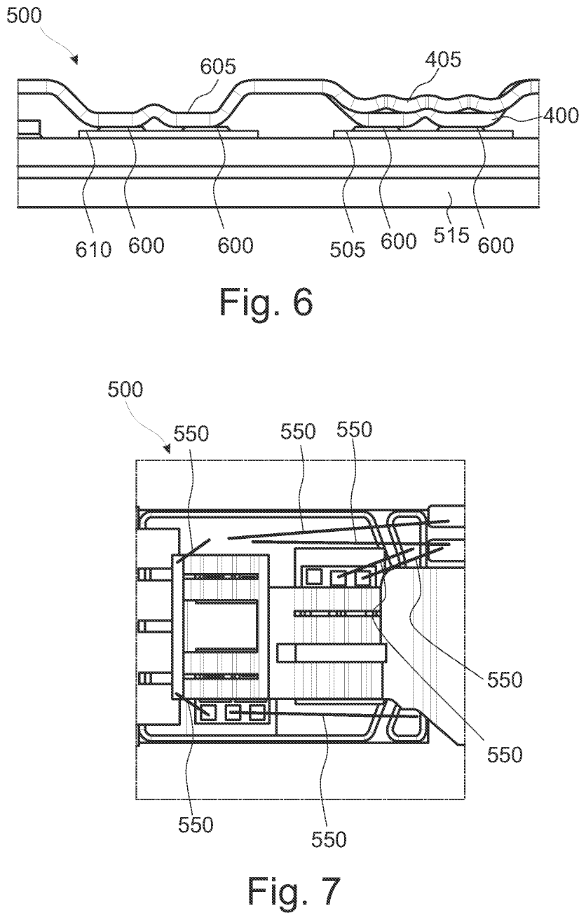

FIG. 6 shows a lateral cross-sectional view of a first bending section 400 and a second bending section 405 of an electrical or electronic module 500 according to one exemplary embodiment. This can be the module 500 described in FIG. 5.

According to one exemplary embodiment, a mechanical connection of the electrical or electronic component 505/semiconductor to the first bending section 400 and the further first bending section is formed, in each case, by one or more sintered or soldered connections 600. According to this exemplary embodiment, the second electrical or electronic component/semiconductor is also mechanically connected to the third and fourth bending sections, in each case, by means of one or more sintered or soldered connections 600. According to this exemplary embodiment, the third electrical or electronic component 610/semiconductor is also mechanically connected to the fifth and sixth bending sections 605, in each case, by means of one or more sintered or soldered connections 600. The second bending section 405, by means of a gap between the second bending section 405 and the component 505, is configured in an isolated arrangement from the component 505. According to this exemplary embodiment, a length of the second bending section 405 corresponds to a length of the first bending section 400.

FIG. 7 shows a schematic view of an electrical or electronic module 500 according to one exemplary embodiment. This can be the module 500 described in FIG. 5 or 6.

FIG. 7 shows a view of the bonding wires 550 in the module 500.

FIG. 8 shows a perspective view of different production stages during an exemplary manufacturing process of a terminal apparatus 300, according to one exemplary embodiment, and of an electrical or electronic module according to one exemplary embodiment. These can be a terminal apparatus 300 described in FIG. 3 or 4, and an electric or electronic module described in one of FIGS. 5 to 7.

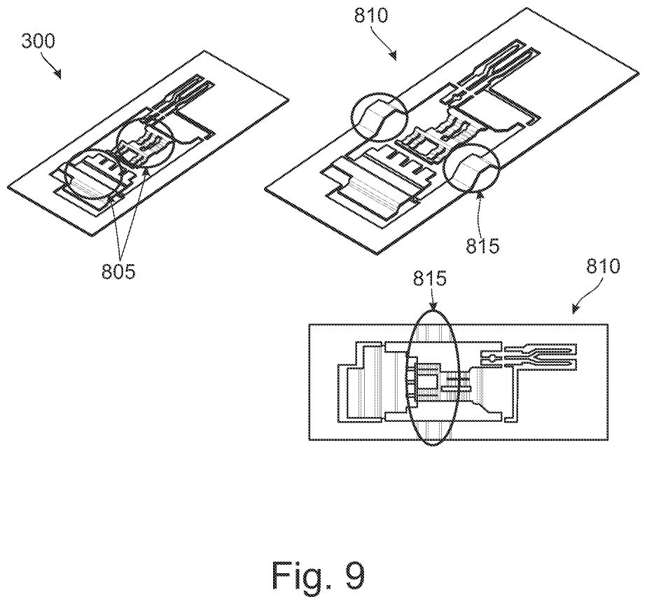

In the manufacturing process for the terminal apparatus 300/leadframe envisaged here, firstly, from a sheet metal blank, contacts 310, 315, 325 have been generated, for example cut-out/stamped-out by means of a die-stamping process 800, in order to obtain the pre-machined sheet metal element 305. In a following first bending process 805, the contacts, in this case specifically all the path sections 330, 380 and optionally also the first electric terminal device 310 have been bent for the purposes of contact-connection in order to produce the terminal apparatus 300. In a following optional second bending process 810, according to this exemplary embodiment, the leadframe, by means of bending or rejoining in the outer region 815 of the sheet metal, has been shortened, such that a minimization of clearances for the contact-connection/overlapping of the first electric terminal device 310 with the second electric terminal device is permitted, c.f. also FIG. 9. In a following sintering and/or soldering process 820, the leadframe has been sintered/soldered to the DBC board and the semiconductors, in order to produce the module. Optionally, the module has then been over-molded in a molding process 825. In a following optional third bending process 830, the control contacts have been bent and/or a residual frame of the leadframe has been removed by cutting/stamping.

FIG. 9 shows a perspective view of different production stages during an exemplary manufacturing process of a terminal apparatus 300 according to one exemplary embodiment. Depending upon the outcomes, this can involve the first bending process 805 and the second bending process 810 described in FIG. 8.

In the first bending process 805, the “drain” and “power source” terminals are bent.

The second bending process 810 advantageously permits a shortening of the leadframe, such that connecting elements at different potentials, in this case the first electric terminal device and the second electric terminal device, can be combined in closer proximity within the module than in existing systems. In other words, in the second bending process 810, two mutually opposing outer regions 815 of the sheet metal are bent, such that the “drain” and “power source” can be configured in an overlapping arrangement.

According to one exemplary embodiment, die-stamping is executed by means of two or more than two individual processes, in order to achieve more complex geometries. Alternatively, the control contacts 320, 365 (gate/Kelvin-source), according to an alternative exemplary embodiment, are previously bent upwards in a first bending process 805 or second bending process 810 in the process chain, rather than in the final step of the process. The first bending process 805 and the second bending process 810, according to one exemplary embodiment, are executed in sequential process steps, either in different installations or in the same installation.

In addition to the embodiment of a 3-chip design represented here, according to different exemplary embodiment, other chip numbers are possible and, correspondingly, more bent path sections are formed on the second electric terminal device. For example, according to an alternative exemplary embodiment, the leadframe layout is configured for a 4-chip design.

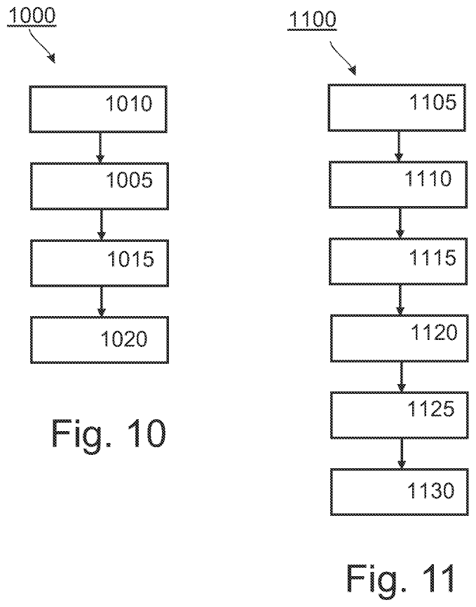

FIG. 10 shows a flow diagram of an exemplary embodiment of a method 1000 for manufacturing a terminal apparatus for connecting at least one electrical or electronic component for an electrical or electronic module. This can be one of the terminal apparatuses described with reference to one of FIGS. 3 to 9.

The method 1000 comprises a bending step 1005. In the bending step 1005, a pre-machined sheet metal element is bent, such that a first electric terminal device for connecting to a first electrical potential, a control terminal having at least one control contact, and a second electric terminal device for connecting to a second electrical potential, which is arranged between the first electric terminal device and the control terminal, are provided, wherein the second electric terminal device has a path section which comprises a first path for contact-connection with a terminal for the second electrical potential of the electrical or electronic component, and at least one second path, which is oriented in parallel with the first path. In the bending step 1005, a first bending section of the first path is bent into a lower plane than a second bending section of the second path in order to form the terminal apparatus.

The bending step 1005 can be the first bending process described in FIG. 8 or 9.

According to this exemplary embodiment, the method 1000 comprises, in an optional manner only, a die-stamping and/or laser cutting step 1010, a further bending step 1015 and/or a shortening step 1020.

In the die-stamping and/or laser cutting step 1010, prior to the bending step 1005, a sheet metal blank is die-stamped or laser cut in order to obtain the pre-machined sheet element. According to one exemplary embodiment, in this case, in the die-stamping and/or laser cutting step 1010, the sheet metal blank is die-stamped or laser cut such that a gap is formed between the first electric terminal device and the path section.

In the further bending step 1015, the control contact is bent in a direction opposite to the path section. In the further bending step 1015, the second control contact can also be bent in a corresponding manner to the control contact.

In the shortening step 1020, an outer region of the sheet metal element is bent and/or brought together in order to arrange the first electric terminal device and the second electric terminal device with an overlap.

FIG. 11 shows a flow diagram of an exemplary embodiment of a method 1100 for manufacturing an electrical or electronic module. This can be an electrical or electronic module described with reference to one of FIGS. 5 to 9.

The method 1100 comprises a resourcing step 1105 and a contact-connection step 1110. In the resourcing step 1105, a terminal apparatus, which has been produced by the employment of the method described in FIG. 10, and the electrical or electronic component are provided. In the contact-connection step 1110, the first bending section is contact-connected with the terminal for the second electrical potential of the electrical or electronic component, in order to produce the electrical or electronic module. In the contact-connection step 1110, the second bending section can furthermore be arranged with a clearance to the terminal for the second electrical potential and/or with a clearance to the further terminal for the first potential of the electrical or electronic component, in order to produce the electrical or electronic module.

According to one exemplary embodiment 1100, the method further comprises a fastening step 1115, a molding step 1120, a further bending step 1125 and/or a removal step 1130.

In the fastening step 1115, the first bending section is soldered or sintered to the terminal for the second electrical potential of the electrical or electronic component and/or the further first bending section is soldered or sintered to a terminal for the first electrical potential of the electrical or electronic component, and/or at least one connecting section of the terminal apparatus is soldered or sintered to a substrate which carries the electrical or electronic component, for example a direct bonded copper substrate, or to another circuit board. In the molding step 1120, at least the path section and the electrical or electronic component which is contact-connected by the first bending section are over-molded. In the further bending step 1125, the control contact is bent in a direction opposite to the path section. In the further bending step, according to one exemplary embodiment, the second control contact is also bent in a corresponding manner to the control contact. In the removal step 1130, an edge region of the sheet metal blank or the pre-machined sheet metal element is removed. For example, in the removal step 1130, the edge region is removed by cutting, laser cutting and/or stamping.

The exemplary embodiments described and represented in the figures have been selected for exemplary purposes only. Different exemplary embodiments can be mutually combined, either in their entirety or with respect to individual features. An exemplary embodiment can also be expanded to include the features of a further exemplary embodiment.

Moreover, the process steps envisaged herein can be repeated, or can be executed in a sequence other than that described.

Where an exemplary embodiment of an “and/or” association between a first feature and a second feature, it is to be understood that the exemplary embodiment, according to one embodiment, comprises both the first and the second feature and, according to another embodiment, comprises only the first feature or the second feature.

### REFERENCE NUMBERS

100 Motor vehicle
105 Wheels
110 Electrical energy store
120 Electric axle drive
130 Power converter
140 Electrical machine
150 Transmission device
231 DC terminals
233 Link capacitor
235 Power modules
237 AC terminals
S1 First power module
S2 Second power module
S3 Third power module
S4 Fourth power module
S5 Fifth power module
S6 Sixth power module
300 Terminal apparatus
305 Pre-machined sheet metal element
310 First electric terminal device
315 Control terminal
320 Control contact
325 Second electric terminal device
330 Path section
335 First path
340 Second path
345 Apparatus for manufacturing a terminal apparatus
350 Output device
355 Bending signal
360 Further bending signal
365 Second control contact
370 Bending direction
375 Further first path
380 Second path section
382 Third path
385 Fourth path
400 First bending section
405 Second bending section
500 Electrical or electronic module
505 Electrical or electronic component
510 Terminal for the second electrical potential of the electrical or electronic component
515 Substrate
520 Further terminal for the first potential of the electrical or electronic component
525 First electrical contact section
530 Second electrical contact section
535 Gate-Anschluss
540 Signal terminal
545 Further signal terminal
550 Bonding wire
600 Sintered or soldered connection
605 Sixth bending section
610 Third electrical or electronic component
800 Die-stamping process
805 First bending process
810 Second bending process
815 Outer region
820 Sintering and/or soldering process
825 Molding process
830 Third bending process
1000 Method for manufacturing a terminal apparatus
1005 Bending step
1010 Die-stamping and/or laser cutting step
1015 Further bending step
1020 Shortening step
1100 Method for manufacturing an electrical or electronic module
1105 Resourcing step
1110 Contact-connection step
1115 Fastening step
1120 Molding step
1125 Further bending step
1130 Removal step

1. A method of manufacturing a terminal apparatus for connecting at least one electrical or electronic component for an electrical or electronic module, the method comprising:
bending a pre-machined sheet metal element comprising:
a first electric terminal device configured to connect to a first electrical potential;
a control terminal having at least one control contact; and
a second electric terminal device arranged between the first electric terminal device and the control terminal and configured to connect to a second electrical potential,
wherein the second electric terminal device has a path section which comprises a first path for contact-connection with a terminal for the second electrical potential of the electrical or electronic component, and at least one second path which is arranged in parallel with the first path, and
wherein the bending includes bending a first bending section of the first path into a lower plane than a second bending section of the second path in order to form the terminal apparatus.

2. The method according to claim 1, wherein, in the bending, a first section length of the first bending section and/or a second section length of the second bending section essentially correspond to a first component length of the electrical or electronic component.

3. The method according to claim 1, comprising bending the first bending section and/or the second bending section into a wave shape.

4. The method according to claim 1, comprising:
prior to bending, die-stamping and/or laser-cutting a sheet metal blank to obtain the pre-machined sheet metal element such that a gap between the first electric terminal device and the path section is generated.

5. The method according to claim 1, comprising bending the control contact in a direction opposite to the path section.

6. The method according to claim 1, comprising bending a further first path of the path section, which is arranged in parallel with the first path, for contact-connection with a further terminal for the first potential of the electrical or electronic component, in a corresponding manner to the first bending section.

7. The method according to claim 1, comprising:
bending the pre-machined sheet metal element such that it further comprises at least one second path section which is arranged between the first electric terminal device and the control terminal, which comprises a third path for contact-connection with a terminal for the second electrical potential of a second electrical or electronic component, and at least one fourth path, which is arranged in parallel with the third path, wherein, a third bending section of the third path is bent into a lower plane than a fourth bending section of the fourth path.

8. The method according to claim 7, comprising bending the third bending section and the fourth bending section of the second path section such that the path section and the second path section are arranged adjacently to one another or one behind the other.

9. The method according to claim 1, comprising:
bending the pre-machined sheet metal element such that it further comprises at least one second path section which is arranged between the first electric terminal device and the control terminal, which comprises a third path for contact-connection with a terminal for the second electrical potential of a second electrical or electronic component, and at least one fourth path, which is arranged in parallel with the third path, wherein, a third bending section and a fourth bending section are bent in a corresponding manner to the first bending section.

10. The method according to claim 9, comprising bending the third bending section and the fourth bending section of the second path section such that the path section and the second path section are arranged adjacently to one another or one behind the other.

11. The method according to claim 1, comprising:
contact-connecting the first bending section with the terminal for the second electrical potential of the electrical or electronic component to produce the electrical or electronic module.

12. An apparatus for manufacturing a terminal apparatus, the apparatus comprising at least one processing device configured to:
execute and/or actuate the manufacture of the terminal apparatus at least by outputting signals to cause bending of a pre-machined sheet metal element comprising:
a first electric terminal device configured to connect to a first electrical potential;
a control terminal having at least one control contact; and
a second electric terminal device arranged between the first electric terminal device and the control terminal and configured to connect to a second electrical potential,
wherein the second electric terminal device has a path section which comprises a first path for contact-connection with a terminal for the second electrical potential of the electrical or electronic component, and at least one second path which is arranged in parallel with the first path, and
wherein the bending includes bending a first bending section of the first path into a lower plane than a second bending section of the second path in order to form the terminal apparatus.

13. A non-transitory machine-readable storage medium, on which a computer program is stored that, when executed by a processing device, cause the processing device to execute and/or actuate manufacture of a terminal apparatus at least by outputting signals to cause bending of a pre-machined sheet metal element comprising:
a first electric terminal device configured to connect to a first electrical potential;
a control terminal having at least one control contact; and
a second electric terminal device arranged between the first electric terminal device and the control terminal and configured to connect to a second electrical potential,
wherein the second electric terminal device has a path section which comprises a first path for contact-connection with a terminal for the second electrical potential of the electrical or electronic component, and at least one second path which is arranged in parallel with the first path, and
wherein the bending includes bending a first bending section of the first path into a lower plane than a second bending section of the second path in order to form the terminal apparatus.

14. A power converter comprising a terminal apparatus which has been manufactured according to the method according to claim 1.

15. An electric axle drive for a motor vehicle comprising at least one electrical machine, a transmission device, and the power converter according to claim 14.

16. A motor vehicle, comprising an electric axle drive according to claim 15.
